(19) United States
(12) Patent Application Publication
(10) Pub. No.: US 2004/0161940 A1
(43) Pub. Date: Aug. 19, 2004

(54) Semiconductor wafer processing method

(76) Inventors: Toshiharu Daii, Tokyo (JP); Erumu Nitta, Tokyo (JP); Masatoshi Wakahara, Tokyo (JP)

Correspondence Address: SMITH, GAMBRELL & RUSSELL, LLP, 1850 M STREET, N.W., SUITE 800, WASHINGTON, DC, 20036, US

(21) Appl. No.: 10/774,529

(22) Filed: Feb. 10, 2004

(30) Foreign Application Priority Data
Feb. 13, 2003 (JP) 2003 - 34508

(51) Int. Cl. H01L 21/302

(52) U.S. Cl. 438/706

(57) ABSTRACT

A semiconductor wafer processing method comprising affixing a protective tape to the front surface of a semiconductor wafer having a plurality of circuits formed on its front surface, grinding the back surface of the semiconductor wafer and then, executing plasma etching of the back surface of the semiconductor wafer, wherein

a tape having an adhesive layer that is hardened by exposure to ultraviolet radiation is used as the protective tape and exposed to ultraviolet radiation to harden the adhesive layer before the back surface of the semiconductor wafer undergoes plasma etching.

### FIELD OF THE INVENTION

The present invention relates to a semiconductor wafer processing method comprising subjecting the back surface of a semiconductor wafer to plasma etching after the back surface of the semiconductor wafer is ground.

### DESCRIPTION OF THE PRIOR ART

In the production process of semiconductor devices, semiconductor chips are produced by forming a circuit in a large number of areas arranged in a lattice form on the front surface of a semiconductor wafer and then, dicing the areas having the circuit formed therein. To improve heat radiation of the semiconductor chips, the semiconductor chips are desirably formed as thin as possible. Also to enable the downsizing of a portable telephone, smart card or personal computer in which a large number of semiconductor chips is used, the semiconductor chips are desirably made as thin as possible. To this end, before the semiconductor wafer is divided into individual semiconductor chips, the back surface of the semiconductor wafer is ground to a predetermined thickness.

A dividing technology called “pre-dicing” has been implemented as a means of separating thinner semiconductor chips from one another. This pre-dicing is a technology for separating individual semiconductor chips from one another by forming dividing grooves having a predetermined depth (corresponding to the final thickness of the semiconductor chips) from the front surface of the semiconductor wafer along streets and then, by grinding the back surface of the semiconductor wafer having the dividing grooves formed on its front surface to expose the dividing grooves, and it is possible to reduce the thickness of the semiconductor chips to 50 μm or less.

However, microcracks or strain produced by grinding remain(s) on the back surface of the ground semiconductor wafer, thereby reducing the deflection strength of the semiconductor chip, decreasing the yield and shortening the life of a product. To cope with these, in the step of processing the semiconductor wafer, after the back surface of the semiconductor wafer is ground, a protective tape is affixed to the front surface having circuits formed thereon, and the back surface is chemically etched to remove the microcracks or strain produced by grinding, for the purpose to enhance the deflection strength of the semiconductor chips and further reduce the thickness of the semiconductor chips.

As this chemical etching, there have already been implemented a wet etching in which a protective tape is affixed to the front surface of a semiconductor wafer having circuits formed thereon and an etchant containing nitric acid and hydrofluoric acid is used and a dry etching in which a mixed gas for generating plasma, which is mainly composed of a fluorine-based gas such as CF₄ or the like and oxygen, is used. The wet etching causes environmental pollution because chemical liquids such as nitric acid and hydrofluoric acid are used, and it requires a waste fluid disposal apparatus for disposing of the used etchant.

Meanwhile, the dry etching is being more and more employed for the etching of a semiconductor wafer because a waste fluid disposal apparatus is not necessary, it is easy to control the etching rate, and influence of etching on a circuit surface is small. In view of these, JP-A 2001-257248 (the term “JP-A” as used herein means an “unexamined published Japanese patent application”) discloses a semiconductor processing apparatus which comprises a dry etching unit making use of plasma etching and a grinding unit.

After a protective tape is affixed to the front surface of a semiconductor wafer having circuits formed thereon and the back surface of the semiconductor wafer is ground, when the semiconductor wafer is placed on the workpiece holding means of a plasma etching device in such a manner that the protective tape side faces the workpiece holding means, and plasma etching of the back surface of the semiconductor wafer is carried out, the adhesive layer of the protective tape is softened and distorted by heat generated at the time of plasma etching, whereby a gap is formed between the circuits formed on the front surface of the semiconductor wafer and the protective tape with the result that the circuit surface is damaged by the entry of a plasma etching gas into the gap. Particularly, when plasma etching is carried out after individual semiconductor chips are separated by the above pre-dicing, the above problem becomes more marked because a gap is formed between adjacent semiconductor chips.

### SUMMARY OF THE INVENTION

It is an object of the present invention to provide a semiconductor wafer processing method capable of exerting plasma etching on the back surface of a semiconductor wafer without causing the distortion of a protective tape affixed to the front surface of the semiconductor wafer.

According to the present invention, the above object is attained by a semiconductor wafer processing method comprising affixing a protective tape to the front surface of a semiconductor wafer having a plurality of circuits formed on its front surface, grinding the back surface of the semiconductor wafer and then, subjecting the back surface of the semiconductor wafer to plasma etching, wherein

a tape having an adhesive layer which is hardened by exposure to ultraviolet radiation is used as the protective tape, and the protective tape is exposed to ultraviolet radiation to harden the adhesive layer before the back surface of the semiconductor wafer undergoes plasma etching.

According to the present invention, there is also provided a semiconductor wafer processing method comprising forming dividing grooves having a predetermined depth along a plurality of streets on the front surface of a semiconductor wafer having a plurality of streets on the front surface in a lattice form and a circuit formed in each of a plurality of areas sectioned by the plurality of streets, affixing a protective tape to the front surface of the semiconductor wafer having the dividing grooves formed thereon, grinding the back surface of the semiconductor wafer until the dividing grooves are exposed to separate into individual circuits, and subjecting the back surface of the semiconductor wafer to plasma etching, wherein

a tape having an adhesive layer that is hardened by exposure to ultraviolet radiation is used as the protective tape, and the protective tape is exposed to ultraviolet radiation to harden the adhesive layer before the back surface of the semiconductor wafer undergoes plasma etching.

### BRIEF DESCRIPTION OF THE DRAWINGS

FIG. 1 is a diagram showing the step of affixing a protective tape in the processing method of the present invention;

FIG. 2 is a diagram showing the step of grinding the back surface in the processing method of the present invention;

FIG. 3 is a diagram showing the step of applying ultraviolet radiation in the processing method of the present invention;

FIG. 4 is a perspective view of a semiconductor wafer to be processed by the processing method of the present invention;

FIG. 5 is a diagram showing the step of forming dividing grooves in the processing method of the present invention;

FIG. 6 is a diagram showing the step of affixing a protective tape in the processing method of the present invention;

FIG. 7 is a diagram showing the step of exposing the dividing grooves in the processing method of the present invention;

FIG. 8 is a diagram showing the step of applying ultraviolet radiation in the processing method of the present invention;

FIG. 9 is a sectional view of a plasma etching device for carrying out plasma etching in the processing method of the present invention;

FIG. 10 is an enlarged sectional view of the principal parts of a lower electrode and an upper electrode constituting the plasma etching device shown in FIG. 9.

### DETAILED DESCRIPTION OF THE PREFERRED EMBODIMENTS

A semiconductor wafer processing method according to a preferred embodiment of the present invention will be described hereinafter with reference to the accompanying drawings.

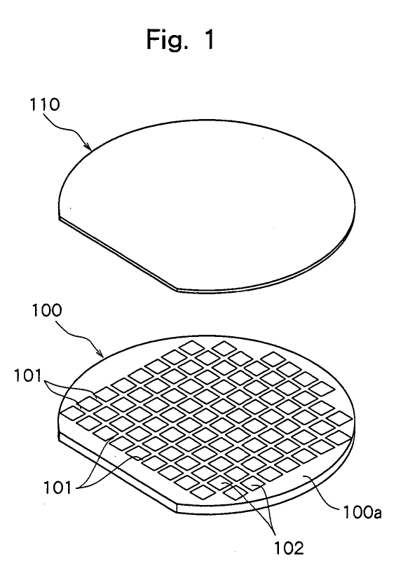

FIGS. 1 to 3 are diagrams showing steps previous to the step of the plasma etching step in the semiconductor wafer processing method of the present invention.

FIG. 1 is a perspective view of a semiconductor wafer and a protective tape. A plurality of streets 101 are formed on the front surface 100a of the semiconductor wafer 100 in a lattice form, and a circuit 102 is formed in each of a plurality of areas sectioned by the plurality of streets 101. A protective tape 110 is affixed onto the front surface 100a of the semiconductor wafer 100 (protective tape affixing step). As the protective tape 110, a so-called UV tape having an adhesive layer that is hardened by exposure to ultraviolet radiation is used.

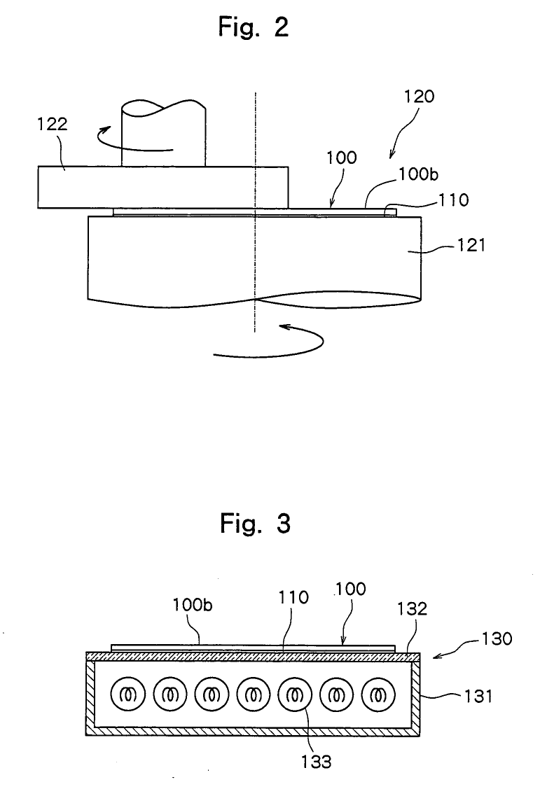

The semiconductor wafer 100 having the protective tape 110 affixed to its front surface 100a is transferred to the step of grinding the back surface of a semiconductor wafer. In the step of grinding the back surface of a semiconductor wafer, as shown in FIG. 2, the semiconductor wafer 100 is placed on a chuck table 121 of a grinding machine 120 in such a manner that the side of protective tape 110 comes in contact with the chuck table 121 (therefore, the back surface 100b faces up), and the semiconductor wafer 100 is suction-held on the chuck table 121 by a suction means that is not shown. The back surface 100b of the semiconductor wafer 100 is ground up to a predetermined thickness by rotating a grinding wheel 122 at 6,000 rpm while rotating the chuck table 121 at 300 rpm, for example, and bringing the grinding wheel into contact with the back surface 100b of the semiconductor wafer 100.

When the back surface 100b of the semiconductor wafer 100 is ground as described above, microcracks or strain produced by grinding remain(s) on the back surface 100b of the semiconductor wafer 100. To remove this microcrack or strain, the back surface 100b of the semiconductor wafer 100 is subjected to plasma etching in the processing method of the present invention. To prevent the protective tape 110 from being softened and distorted by heat at the time of plasma etching, the step of applying ultraviolet radiation is carried out as shown in FIG. 3 in the present invention. That is, as shown in FIG. 3, the semiconductor wafer 100 is placed at a predetermined position on an upper plate 132 which is a glass plate constituting the housing 131 of an ultraviolet illuminator 130 in such a manner that the protective tape 110 comes into contact with the upper plate 132, and ultraviolet lamps 133 installed in the housing 131 are turned on to apply ultraviolet radiation to the protective tape 110. Since the protective tape 110 is a so-called UV tape having an adhesive layer that is hardened by exposure to ultraviolet radiation as described above, the adhesive layer of the protective tape 110 is caused to harden. After the step of applying ultraviolet radiation, the routine proceeds to the plasma etching step which will be described hereinafter.

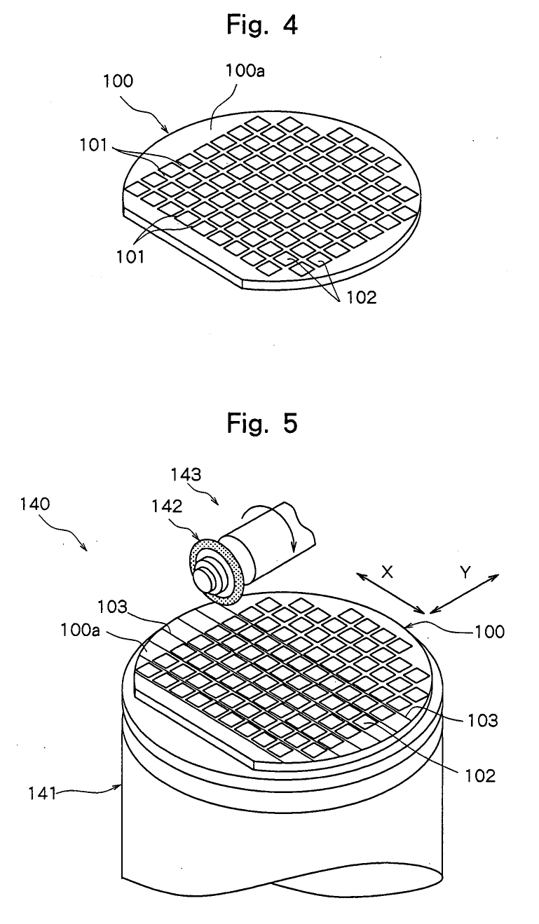

Next, other variations of the steps previous to the plasma etching step in the semiconductor wafer processing method of the present invention will be described with reference to FIGS. 4 to 8.

FIG. 4 is a perspective view of a semiconductor wafer. A plurality of streets 101 are formed on the front surface 100a of the semiconductor wafer 100 in a lattice form, and a circuit 102 is formed in each of a plurality of areas sectioned by the plurality of streets 101, like the semiconductor wafer shown in FIG. 1. To divide the thus constituted semiconductor wafer 100 into individual semiconductor chips, the step of forming dividing grooves having a predetermined depth (corresponding to the final thickness of each semiconductor chip) along the streets 101 formed on the front surface 100a of the semiconductor wafer 100 is first carried out. A cutting machine 140 which is generally used as a dicing machine shown in FIG. 5 may be used in this dividing groove forming step. That is, the cutting machine 140 comprises a chuck table 141 having a suction-holding means and a cutting means 143 having a cutting blade 142. The semiconductor wafer 100 is held on the chuck table 141 of this cutting machine 140 in such a manner that its front surface 100a faces up, and the dividing grooves 103 are formed along the streets 101 by moving the chuck table 141 in a cutting direction shown by an arrow X while rotating the cutting blade 142 of the cutting means 143, and further by moving the cutting means 142 in an index-feeding direction shown by an arrow Y by the distance between adjacent streets. The depth of the dividing grooves 103 is set to a depth corresponding to the final thickness of each semiconductor chip to be divided.

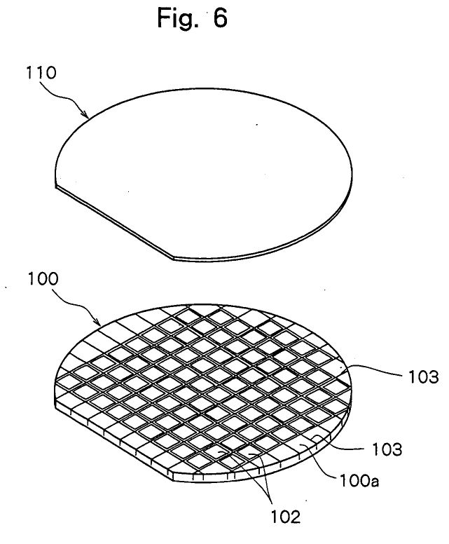

After the dividing grooves 103 having a predetermined depth are formed along the streets 101 on the front surface 100a of the semiconductor wafer 100 in the above dividing groove forming step, a protective tape 110 is affixed to the front surface 100a of the semiconductor wafer 100 as shown in FIG. 6 (protective tape affixing step). A so-called UV tape having an adhesive layer that is hardened by exposure to ultraviolet radiation is used as the protective tape 110.

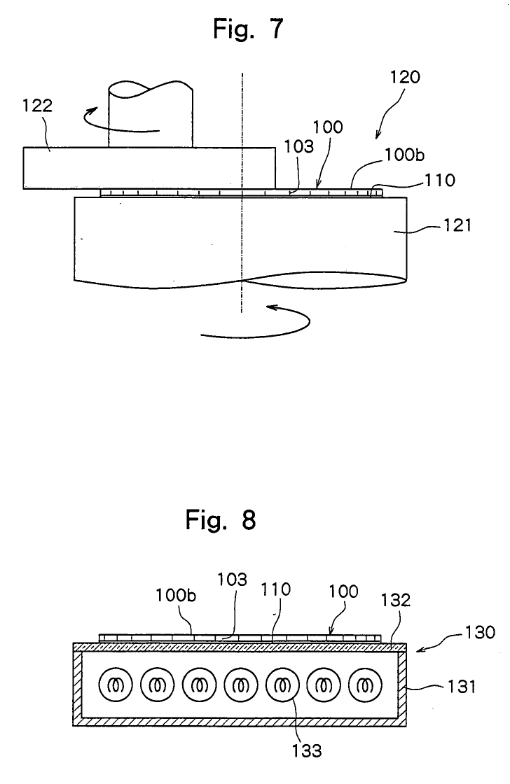

The semiconductor wafer 100 having the protective tape 110 affixed to its front surface 100a is transferred to a dividing groove exposing step. In this dividing groove exposing step, the semiconductor wafer 100 is placed on a chuck table 121 of a grinding machine 120 in such a manner that the protective tape 110 comes into contact with the chuck table 121 as shown in FIG. 7 (therefore, the back surface 100b faces up) and suction-held on the chuck table 121 by a suction means that is not shown. The back surface 100b of the semiconductor wafer 100 is ground by rotating a grinding wheel 122 at 6,000 rpm while rotating the chuck table 121 at 300 rpm, for example, and bringing the grinding wheel to the back surface 100b of the semiconductor wafer 100 until the dividing grooves 103 are exposed to the back surface 100b. By grinding until the dividing grooves 103 are exposed, the semiconductor wafer 100 is divided into individual semiconductor chips. Since the protective tape 110 is affixed to the front surfaces of the semiconductor chips, the semiconductor chips do not fall apart and the state of the semiconductor wafer 100 is maintained.

As described above, when the back surface 100b of the semiconductor wafer 100 is ground, microcracks or strain produced by grinding remain(s) on the back surfaces of the semiconductor chips. To remove the microcracks or strain, in the processing method of the present invention, the back surfaces of the individual semiconductor chips in the shape of the semiconductor wafer 100 are subjected to plasma etching. To prevent the protective tape 110 from being softened and distorted by heat at the time of plasma etching, the step of applying ultraviolet radiation is carried out in the present invention as shown in FIG. 8. The step of applying ultraviolet radiation shown in FIG. 8 is carried out by placing the semiconductor wafer 100 at a predetermined position on the upper plate 132 that is a glass plate constituting the housing 131 of the ultraviolet illuminator 130 in such a manner that the protective tape 110 side comes into contact with the upper plate 132 and then, by turning on the ultraviolet lamps 133 installed in the housing 131 to apply ultraviolet radiation to the protective tape 110, like in the step of applying ultraviolet radiation shown in FIG. 3. Since the protective tape 110 is a so-called UV tape having an adhesive layer that is hardened by exposure to ultraviolet radiation as described above, the adhesive layer of the protective tape 110 is caused to harden. After the step of applying ultraviolet radiation is carried out, the routine proceeds to a plasma etching step which will be described hereinafter.

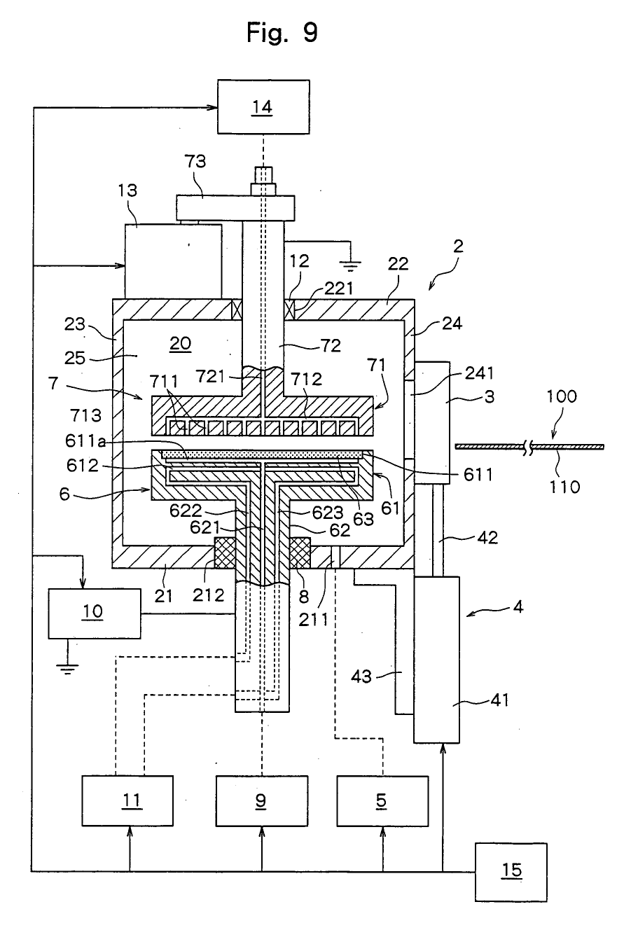

Next, a plasma etching device for carrying out plasma etching in the semiconductor wafer processing method of the present invention will be described with reference to FIG. 9.

The plasma etching device shown in FIG. 9 has a housing 2 for forming a closed space 20. This housing 2 consists of a bottom wall 21, an upper wall 22, a right-side wall 23 and a left-side wall 24, a rear side wall 25 and a front side wall (not shown), and an opening 241 for taking in and out a workpiece is provided in the right-side wall 24. A gate 3 for opening and closing the opening 241 is arranged outside the opening 241 such that it can be moved in a vertical direction. This gate 3 is operated by a gate moving means 4. The gate moving means 4 comprises an air cylinder 41 and a piston rod 42 connected to a piston (not shown) installed in the air cylinder 41, the air cylinder 41 is mounted to the bottom wall 21 of the above housing 2 by a bracket 43, and the end (upper end in the figure) of the piston rod 42 is connected to the above gate 3. When the gate 3 is opened by this gate moving means 4, the semiconductor wafer 100 as a workpiece can be taken in, or out from, the opening 241. An exhaust port 211 is formed in the bottom wall 21 constituting the housing 2 and is connected to a gas exhaust means 5.

A lower electrode 6 and an upper electrode 7 are arranged in the closed space 20 formed by the above housing 2 in such a manner that they are opposite to each other.

The lower electrode 6 is made of a conductive material and comprises a disk-like workpiece holding portion 61 and a columnar support portion 62 projecting from the center portion of the under surface of the workpiece holding portion 61. The lower electrode 6 thus constituted by the workpiece holding portion 61 and the columnar support portion 62 is supported in a state of the support portion 62 being inserted into a hole 212 formed in the bottom wall 21 of the housing 2 and being sealed up by the bottom wall 21 through an insulating material 8. The lower electrode 6 thus supported to the bottom wall 21 of the housing 2 is electrically connected to a high-frequency power source 10 via the support portion 62.

A circular fitting depression 611 which is open at the top is provided in the top portion of the workpiece holding portion 62 constituting the lower electrode 6, and a disk-like suction-holding member 63 made of a porous ceramic material is fitted to the fitting depression 611. A chamber 611a formed below the suction-holding member 63 in the fitting depression 611 is communicated with a suction means 9 through a passage 621 formed in the workpiece holding portion 61 and the support portion 62. Therefore, when a workpiece is placed on the suction-holding member 63 and the passage 621 is communicated with a negative pressure source by activating the suction means 9, a negative pressure acts on the chamber 611a to suction-hold the workpiece mounted on the suction-holding member 63. Further, by activating the suction means 9 to allow the passage 621 to open to the air, the suction-holding of the workpiece by the suction-holding member 63 is canceled.

A cooling passage 612 is formed in a lower portion of the workpiece holding portion 61 constituting the lower electrode 6. One end of the cooling passage 612 is communicated with a refrigerant introduction passage 622 formed in the support portion 62, and the other end of the cooling passage 612 is communicated with a refrigerant exhaust passage 623 formed in the support portion 62. The refrigerant introduction passage 622 and the refrigerant exhaust passage 623 are communicated with a refrigerant supply means 11. Therefore, when the refrigerant supply means 11 is activated, a refrigerant is circulated through the refrigerant introduction passage 622, cooling passage 612 and refrigerant exhaust passage 623. As a result, heat generated at the time of plasma etching, which is later described, is transmitted from the lower electrode 6 to the refrigerant, thereby preventing an abnormal rise in the temperature of the lower electrode 6.

The above upper electrode 7 is made of a conductive material, and comprises a disk-like gas ejection portion 71 and a columnar support portion 72 projecting from the center portion of the top surface of the gas ejection portion 71. The upper electrode 7 thus constituted by the gas ejection portion 71 and the columnar support portion 72 is supported such that the gas ejection portion 71 is arranged opposite to the workpiece holding portion 61 constituting the lower electrode 6, the support portion 72 is inserted into a hole 221 formed in the upper wall 22 of the housing 2, and the upper electrode 7 can be moved in a vertical direction by a sealing member 12 fitted in the hole 221. A connector member 73 is mounted on the top end of the support portion 72 and connected to a lifting drive means 13. The upper electrode 7 is grounded by the support portion 72.

A plurality of spout nozzles 711 which are open to the under surface are formed in the disk-like gas ejection portion 71 constituting the upper electrode 7. The plurality of spout nozzles 711 are communicated with a gas supply means 14 through a passage 712 formed in the gas ejection portion 71 and a passage 721 formed in the support portion 72. The gas supply means 14 supplies a mixed gas for generating plasma, which is mainly composed of a fluorine-based gas such as CF₄ or the like and oxygen.

The plasma etching device in the illustrated embodiment has a control means 15 for controlling the above gate moving means 4, gas exhaust means 5, suction means 9, high-frequency power source 10, refrigerant supply means 11, lifting drive means 13 and gas supply means 14. To this control means 15 are input data on the inside pressure of the closed space 20 formed by the housing 2 from the gas exhaust means 5, data on the refrigerant temperature (e.g., electrode temperature) from the refrigerant supply means 11, and data on the flow rate of the gas from the gas supply means 14, and the control means 15 outputs a control signal based on these data to the above respective means.

The plasma etching device in the illustrated embodiment is constituted as described above, and an example in which the plasma etching (dry etching) is carried out on the back surface of the semiconductor wafer 100 subjected to the step of applying ultraviolet radiation as described above, will be described hereinbelow.

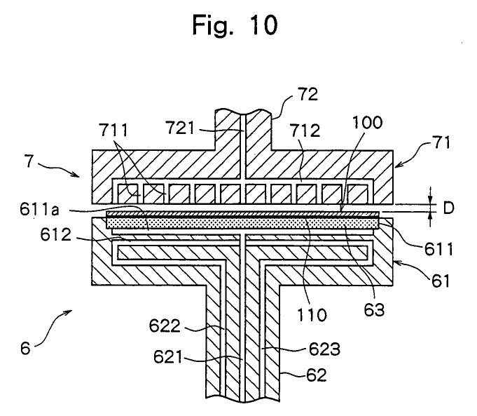

To carry out plasma etching (dry etching) on the semiconductor wafer 100 which has been ground to a predetermined thickness and has undergone the step of applying ultraviolet radiation, the gate moving means 4 is first activated to move down the gate 3 in FIG. 9 so as to open the opening 241 formed in the right-side wall 24 of the housing 2. Then, the above semiconductor wafer 100 is carried into the closed space 20 formed by the housing 2 from the opening 241 by a conveyor means (not shown) in such a manner that the protective tape 110 side faces down (therefore, the back surface 100b faces up), and placed on the suction-holding member 63 of the workpiece holding portion 61 constituting the lower electrode 6 in such a manner the protective tape 110 comes into contact with the suction-holding member 63. At this point, the upper electrode 7 is, in advance, moved up by operating the vertical drive means 13. Then, by operating the suction means 9 to exert negative pressure on the chamber 611a, the semiconductor wafer 100 is suction-held on the suction-holding member 63 (see FIG. 10).

When the semiconductor wafer 100 is suction-held on the suction-holding member 63, the gate moving means 4 is operated to move up the gate 3 in FIG. 9 so as to close the opening 241 formed in the right-side wall 24 of the housing 2. The upper electrode 7 is lowered by activating the lifting drive means 13 so that the distance between the under surface of the gas ejection portion 71 constituting the upper electrode 7 and the top surface of the semiconductor wafer 100 held on the workpiece holding portion 61 constituting the lower electrode 6 is brought to a predetermined distance between the electrodes (D) suitable for plasma etching. This distance between the electrodes (D) is set to 10 mm in the illustrated embodiment.

Thereafter, the gas exhaust means 5 is operated to evacuate the closed space 20 formed by the housing 2. When the closed space 20 is evacuated, the gas supply means 14 is operated to supply a mixed gas of a fluorine-based gas and oxygen gas as a plasma generating gas into the upper electrode 7. The mixed gas supplied from the gas supply means 14 goes through the passage 721 formed in the support portion 72 and the passage 712 formed in the gas ejection portion 71 is ejected toward the back surface 100b of the semiconductor wafer 100 held on the suction-holding member 63 of the lower electrode 6 from the plurality of nozzles 711. The inside gas pressure of the closed space 20 is maintained at a predetermined level. While the mixed gas for generating plasma is thus supplied, high-frequency voltage is applied between the lower electrode 6 and the upper electrode 7 from the high-frequency power source 10. Thereby, plasma discharge is generated in the space between the lower electrode 6 and the upper electrode 7 to etch the back surface of the semiconductor wafer 100 by the function of an active substance formed by this plasma discharge.

The above plasma etching is continuously carried out until the thickness of the semiconductor wafer 100 becomes a target value. Thereby, microcracks formed on the back surface of the semiconductor wafer 100 are removed by this grinding. Since the microcracks are generally formed to a depth of 3 to 5 μm, the microcracks on the semiconductor wafer 100 processed up to a target thickness are completely removed by grinding the semiconductor wafer 100 to a thickness larger than its target thickness by the thickness of the microcracks and then, performing plasma etching by the thickness of the dry etching.

The temperature becomes high at the time of the above plasma etching, and the temperature of the protective tape 110 affixed to the front surface 100a of the semiconductor wafer 100 also becomes as high as about 150° C. However, as the adhesive layer of this protective tape 110 has been hardened by exposure to ultraviolet radiation, it is not distorted during plasma etching. Therefore, it is possible to prevent a problem that the plasma etching gas enters into the gap formed between the circuits formed on the front surface of the semiconductor wafer and the protective tape due to the distortion of the protective tape 110 to damage the circuit surface.

According to the present invention, since a tape having an adhesive layer that is hardened by exposure to ultraviolet radiation is used as the protective tape affixed to the front surface of the semiconductor wafer and the adhesive layer is hardened by exposing the protective tape to ultraviolet radiation before the back surface of the semiconductor wafer undergoes plasma etching, the protective tape is not softened and distorted by heat at the time of plasma etching. Accordingly, it is possible to prevent a problem that the plasma etching gas enters into the gap formed between the circuits formed on the front surface of the semiconductor wafer and the protective tape due to the distortion of the protective tape to damage the circuit surface. Particularly, although in so-called pre-dicing, the dividing grooves are exposed to the back surface of the semiconductor wafer and an etching gas easily enters through the grooves, the integration of the tape with the separated chips is improved because the adhesive layer of the protective tape is hardened by exposure to ultraviolet radiation. Hence, the circuits are not damaged.

We claim:

1. A semiconductor wafer processing method comprising affixing a protective tape to the front surface of a semiconductor wafer having a plurality of circuits formed on its front surface, grinding the back surface of the semiconductor wafer and then, subjecting the back surface of the semiconductor wafer to plasma etching, wherein
a tape having an adhesive layer that is hardened by exposure to ultraviolet radiation is used as the protective tape and the protective tape is exposed to ultraviolet radiation to harden the adhesive layer before the back surface of the semiconductor wafer undergoes plasma etching.

2. A semiconductor wafer processing method comprising forming dividing grooves having a predetermined depth along a plurality of streets on the front surface of a semiconductor wafer having a plurality of streets on the front surface in a lattice form and a circuit formed in each of a plurality of areas sectioned by the plurality of streets, affixing a protective tape to the front surface of the semiconductor wafer having the dividing grooves formed thereon, grinding the back surface of the semiconductor wafer until the dividing grooves are exposed to separate into individual circuits and then, executing plasma etching of the back surface of the semiconductor wafer, wherein
a tape having an adhesive layer which is hardened by exposure to ultraviolet radiation is used as the protective tape, and the protective tape is exposed to ultraviolet radiation to harden the adhesive layer before the back surface of the semiconductor wafer undergoes plasma etching.
